(19) United States
(12) Patent Application Publication
(10) Pub. No.: US 2025/0233012 A1
(43) Pub. Date: Jul. 17, 2025

(54) SEMICONDUCTOR STRUCTURE

(71) Applicant: Winbond Electronics Corp., Taichung City (TW)

(72) Inventor: Hung-Yu Wei, Kaohsiung (TW)

(73) Assignee: Winbond Electronics Corp., Taichung City (TW)

(21) Appl. No.: 18/925,059

(22) Filed: Oct. 24, 2024

(30) Foreign Application Priority Data
Jan. 11, 2024 (TW) 113101270

(51) Int. Cl. H01L 21/762; H01L 21/764; H01L 21/768

(52) U.S. Cl. CPC H01L 21/76224; H01L 21/764; H01L 21/76831; H10D 1/47

(57) ABSTRACT

A semiconductor structure including a substrate and an isolation structure is provided. The substrate includes a device region. The isolation structure is located in the substrate. The isolation structure surrounds the device region. The isolation structure includes a first dielectric layer and a second dielectric layer. The first dielectric layer and the second dielectric layer are located in the substrate. The first dielectric layer is located between the second dielectric layer and the substrate. The second dielectric layer includes a first portion and a second portion. The second portion is located on the first portion. The distance between the second portion and the substrate in the device region is greater than the distance between the first portion and the substrate in the device region.

### CROSS-REFERENCE TO RELATED APPLICATION

This application claims the priority benefit of Taiwan application serial no. 113101270, filed on Jan. 11, 2024. The entirety of the above-mentioned patent application is hereby incorporated by reference herein and made a part of this specification.

### BACKGROUND

### Technical Field

The invention relates to a semiconductor structure, and particularly relates to a semiconductor structure including an isolation structure.

### Description of Related Art

In the semiconductor structure, the charges will accumulate in the isolation structure, and the parasitic capacitance will be generated between the charges in the isolation structure and the substrate, thereby reducing the electrical performance of the semiconductor device. In addition, the stress caused by the isolation structure will also reduce the electrical performance of the semiconductor device. Therefore, how to effectively reduce the parasitic capacitance between the charges accumulated in the isolation structure and the substrate and the stress caused by the isolation structure is the goal of continuous efforts.

### SUMMARY

The invention provides a semiconductor structure, which can effectively reduce the parasitic capacitance between the charges accumulated in the isolation structure and the substrate and the stress caused by the isolation structure.

The invention provides a semiconductor structure, which includes a substrate and an isolation structure. The substrate includes a device region. The isolation structure is located in the substrate. The isolation structure surrounds the device region. The isolation structure includes a first dielectric layer and a second dielectric layer. The first dielectric layer and the second dielectric layer are located in the substrate. The first dielectric layer is located between the second dielectric layer and the substrate. The second dielectric layer includes a first portion and a second portion. The second portion is located on the first portion. The distance between the second portion and the substrate in the device region is greater than the distance between the first portion and the substrate in the device region.

The invention provides another semiconductor structure, which includes a substrate, an isolation structure, and a semiconductor device. The substrate includes a device region. The isolation structure is located in the substrate. The isolation structure surrounds the device region. The isolation structure includes a first dielectric layer and a second dielectric layer. The first dielectric layer and the second dielectric layer are located in the substrate. The first dielectric layer is located between the second dielectric layer and the substrate. The second dielectric layer includes a first portion and a second portion. The second portion is located on the first portion. The distance between the second portion and the substrate in the device region is greater than the distance between the first portion and the substrate in the device region. The semiconductor device is located in the device region. The semiconductor device includes a gate, a gate dielectric layer, a first doped region, and a second doped region. The gate is located on the substrate. The gate dielectric layer is located between the gate and the substrate. The first doped region and the second doped region are located in the substrate on two sides of the gate.

Based on the above description, in the semiconductor structure according to the invention, the second dielectric layer includes the first portion and the second portion. The second portion is located on the first portion. The distance between the second portion and the substrate in the device region is greater than the distance between the first portion and the substrate in the device region. Therefore, the parasitic capacitance between the charges accumulated in the second portion of the isolation structure and the substrate in the device region and the stress caused by the second portion of the isolation structure can be effectively reduced, thereby improving the electrical performance of the semiconductor device located in the device region.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view of a semiconductor structure according to some embodiments of the invention.

FIGS. 1B and 1C are cross-sectional views of a semiconductor structure according to other embodiments of the invention.

FIG. 2 is a top view of the semiconductor structure of FIG. 1A.

FIGS. 3A, 3B, 3C, 4A, 4B, 4C, 5A, 5B and 5C are cross-sectional views of a semiconductor structure according to other embodiments of the invention.

### DESCRIPTION OF THE EMBODIMENTS

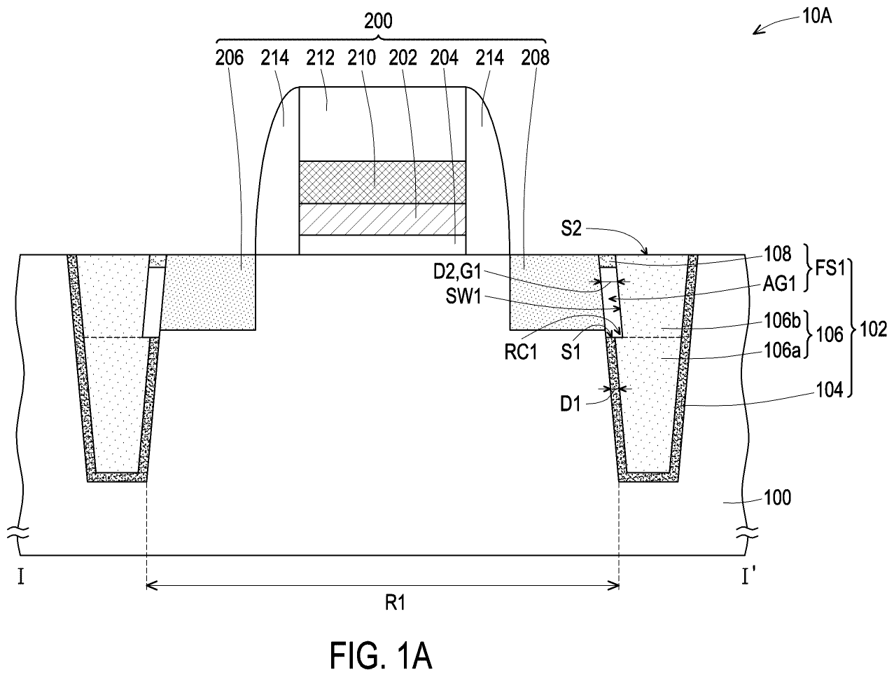

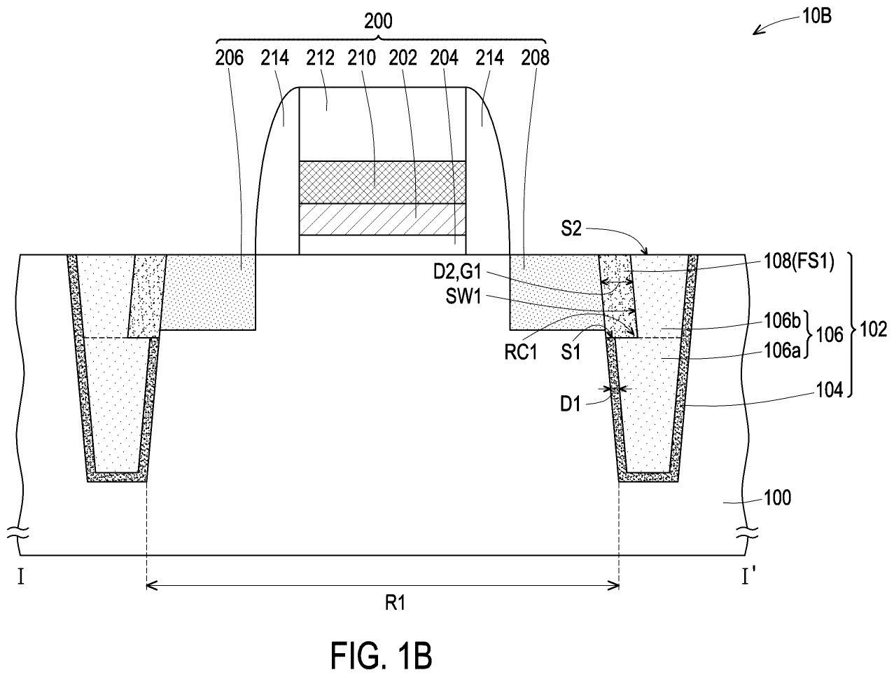

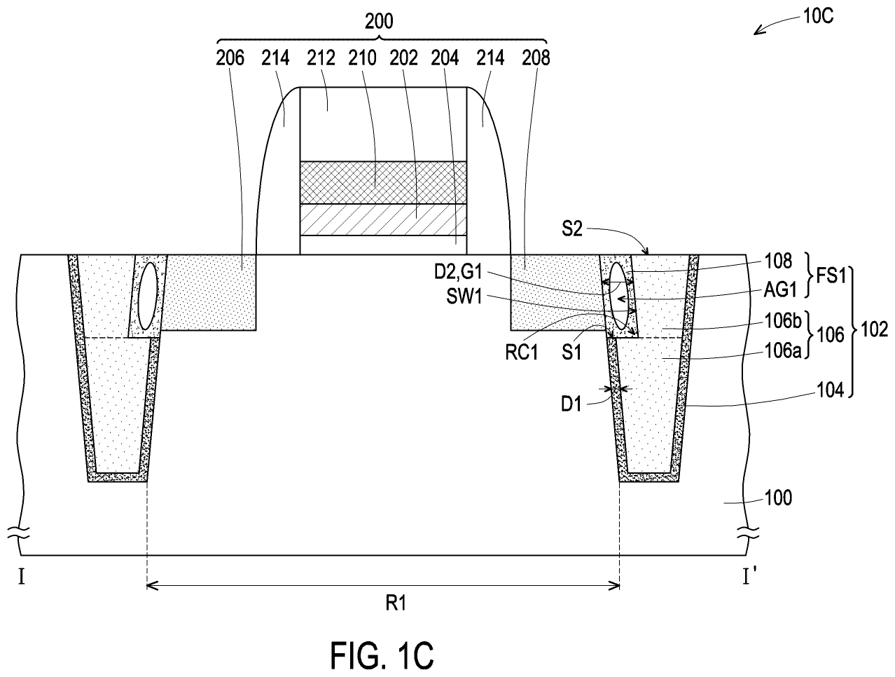

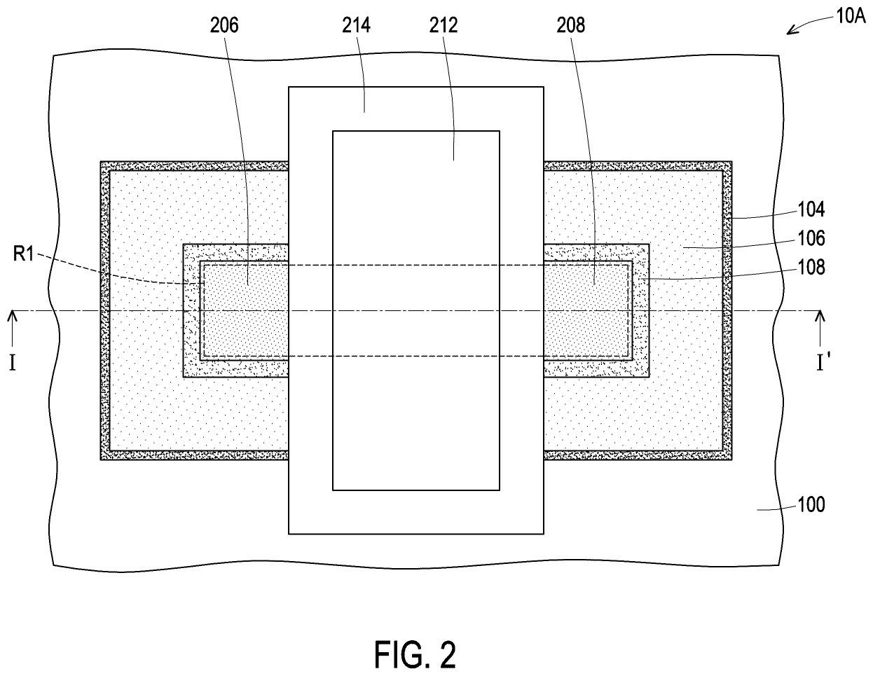

Referring to FIG. 1A and FIG. 2, a semiconductor structure 10A includes a substrate 100 and an isolation structure 102. The substrate 100 includes a device region R1. The device region R1 may be a semiconductor device region. In some embodiments, the device region R1 may be an active device region or a passive device region. In some embodiments, the device region R1 may be a transistor device region or a resistor device region. In the present embodiment, the device region R1 is, for example, a transistor device region, but the invention is not limited thereto. The semiconductor structure 10A may further include a semiconductor device 200. The semiconductor device 200 is located in the device region R1. In some embodiments, the semiconductor device 200 may be an active device or a passive device. In some embodiments, the semiconductor device 200 may be a transistor device or a resistor device. In the present embodiment, the semiconductor device 200 is, for example, a transistor device, but the invention is not limited thereto.

The isolation structure 102 is located in the substrate 100. The isolation structure 102 surrounds the device region R1. The isolation structure 102 includes a dielectric layer 104 and a dielectric layer 106. The dielectric layer 104 and the dielectric layer 106 are located in the substrate 100. The dielectric layer 104 is located between the dielectric layer 106 and the substrate 100. The dielectric layer 104 and the dielectric layer 106 may surround the device region R1. In some embodiments, the dielectric constant of the dielectric layer 104 may be smaller than the dielectric constant of the dielectric layer 106. In some embodiments, the material of the dielectric layer 104 is, for example, oxide (e.g., silicon oxide). In some embodiments, the material of the dielectric layer 106 is, for example, nitride (e.g., silicon nitride).

The dielectric layer 106 includes a first portion 106a and a second portion 106b. The second portion 106b is located on the first portion 106a. The second portion 106b may be located directly above the first portion 106a. The first portion 106a and the second portion 106b may be integrally formed. The distance D2 between the second portion 106b and the substrate 100 in the device region R1 is greater than the distance D1 between the first portion 106a and the substrate 100 in the device region R1. Therefore, the parasitic capacitance between the charges accumulated in the second portion 106b of the isolation structure 102 and the substrate 100 in the device region R1 and the stress caused by the second portion 106b of the isolation structure 102 can be effectively reduced, thereby improving the electrical performance of the semiconductor device 200 located in the device region R1.

The dielectric layer 106 may have a recess RC1. The recess RC1 may be adjacent to the device region R1. The recess RC1 may be located between the second portion 106b and the substrate 100 in the device region R1. The upper surface S1 of the dielectric layer 104 adjacent to the device region R1 may be lower than the top surface S2 of the dielectric layer 106. The dielectric layer 104 is not in direct contact with the sidewall SW1 of the second portion 106b adjacent to the device region R1.

There may be a gap G1 between the second portion 106b and the substrate 100 in the device region R1. The isolation structure 102 may further include a filling structure FS1. The filling structure FS1 is located between the second portion 106b and the substrate 100 in the device region R1. In the present embodiment, the filling structure FS1 may include a filling layer 108 and an air gap AG1. In the present embodiment, the filling layer 108 is only located between the top portion of the second portion 106b and the substrate 100 in the device region R1. The filling layer 108 may seal the top portion of the gap G1. The filling layer 108 may surround the device region R1. In some embodiments, the material of the filling layer 108 is, for example, oxide (e.g., silicon oxide).

The air gap AG1 is located between the second portion 106b and the substrate 100 in the device region R1, between the filling layer 108 and the dielectric layer 104, and between the filling layer 108 and the first portion 106a. In some embodiments, the air gap AG1 may be in direct contact with the substrate 100, the filling layer 108, the dielectric layer 104, the first portion 106a, and the second portion 106b. The air gap AG1 may surround the device region R1. The dielectric constant of the filling layer 108 and the dielectric constant of the air gap AG1 may be smaller than the dielectric constant of the dielectric layer 106, thereby further reducing the parasitic capacitance between the charges accumulated in the second portion 106b of the isolation structure 102 and the substrate 100 in the device region R1. Therefore, the electrical performance of the semiconductor device 200 located in the device region R1 can be improved. In addition, since the air gap AG1 is located between the second portion 106b and the substrate 100 in the device region R1, the impact of the stress caused by the second portion 106b of the isolation structure 102 on the substrate 100 in the device region R1 can be effectively reduced, thereby improving the electrical performance of the semiconductor device 200 located in the device region R1.

The semiconductor device 200 may include a gate 202, a gate dielectric layer 204, a doped region 206, and a doped region 208. The gate 202 is located on the substrate 100. In some embodiments, the material of the gate 202 is, for example, doped polysilicon. The gate dielectric layer 204 is located between the gate 202 and the substrate 100. In some embodiments, the material of the gate dielectric layer 204 is, for example, oxide (e.g., silicon oxide). The doped region 206 and the doped region 208 are located in the substrate 100 on two sides of the gate 202. The doped region 206 and the doped region 208 may be respectively used as one and the other of the source region and the drain region.

In some embodiments, the semiconductor device 200 may further include at least one of a conductive layer 210, a hardmask layer 212, and a spacer 214. The conductive layer 210 is located on the gate 202. In some embodiments, the conductive layer 210 includes a metal silicide layer, a metal layer, or a combination thereof. In some embodiments, the material of the conductive layer 210 is, for example, nickel (Ni), nickel silicide (NiSi), cobalt (Co), cobalt silicide (CoSi), tungsten (W), tungsten silicide (WSi), or a combination thereof. The hardmask layer 212 is located on the conductive layer 210. In some embodiments, the material of the hardmask layer 212 is, for example, nitride (e.g., silicon nitride). The spacer 214 is located on the sidewall of the gate 202, the sidewall of the gate dielectric layer 204, the sidewall of the conductive layer 210, and the sidewall of the hardmask layer 212. The spacer 214 may be a single-layer structure or a multilayer structure. In some embodiments, the material of the spacer 214 is, for example, oxide (e.g., silicon oxide), nitride (e.g., silicon nitride), or a combination thereof.

In other embodiments, when there is the device region R1 on one side of the isolation structure 102 and another device region (not shown) on another side of the isolation structure 102, the distance between the second portion 106b and the substrate 100 in another device region may be greater than the distance between the first portion 106a and the substrate 100 in another device region.

Based on the above embodiments, in the semiconductor structure 10A, the dielectric layer 106 includes the first portion 106a and the second portion 106b. The second portion 106b is located on the first portion 106a. The distance D2 between the second portion 106b and the substrate 100 in the device region R1 is greater than the distance D1 between the first portion 106a and the substrate 100 in the device region R1. Therefore, the parasitic capacitance between the charges accumulated in the second portion 106b of the isolation structure 102 and the substrate 100 in the device region R1 and the stress caused by the second portion 106b of the isolation structure 102 can be effectively reduced, thereby improving the electrical performance of the semiconductor device 200 located in the device region R1.

Referring to FIG. 1A and FIG. 1B, the difference between the semiconductor structure 10B of FIG. 1B and the semiconductor structure 10A of FIG. 1A is as follows. In the semiconductor structure 10B, the filling layer 108 may fill up the gap G1, and there is no air gap in the filling layer 108. In addition, in FIG. 1A and FIG. 1B, the same or similar components are denoted by the same reference symbols, and the description thereof is omitted.

Referring to FIG. 1A and FIG. 1C, the difference between the semiconductor structure 10C of FIG. 1C and the semiconductor structure 10A of FIG. 1A is as follows. In the semiconductor structure 10C, the filling layer 108 fills the gap G1, the filling layer 108 may seal the gap G1, the air gap AG1 is located in the filling layer 108, and the air gap AG1 may be surrounded by the filling layer 108. In the semiconductor structure 10C, the air gap AG1 is not in direct contact with the substrate 100, the dielectric layer 104, and the dielectric layer 106. In addition, in FIG. 1A and FIG. 1C, the same or similar components are denoted by the same reference symbols, and the description thereof is omitted.

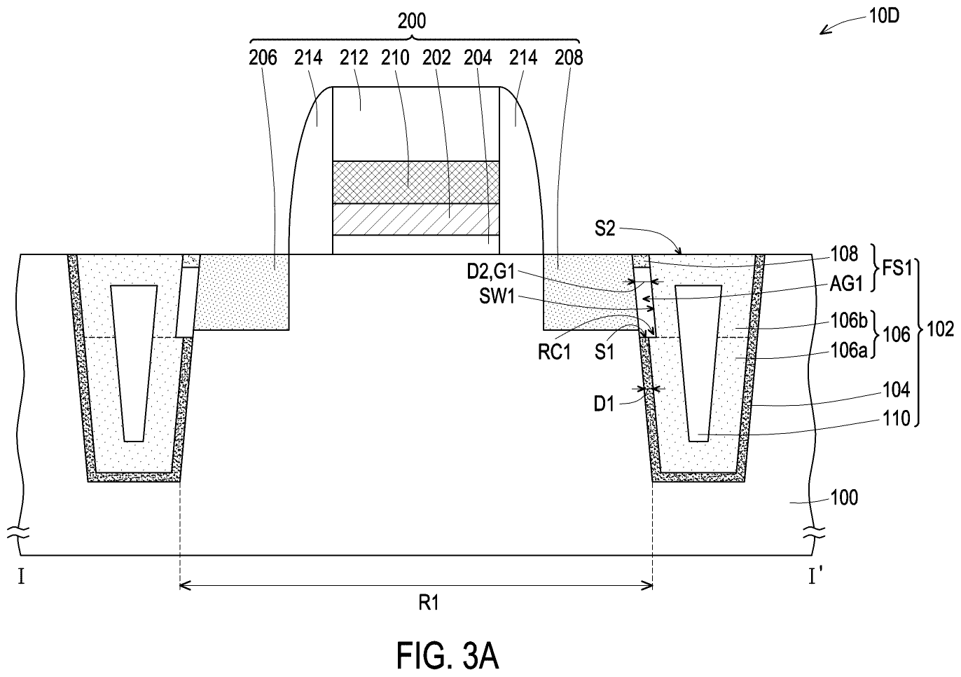

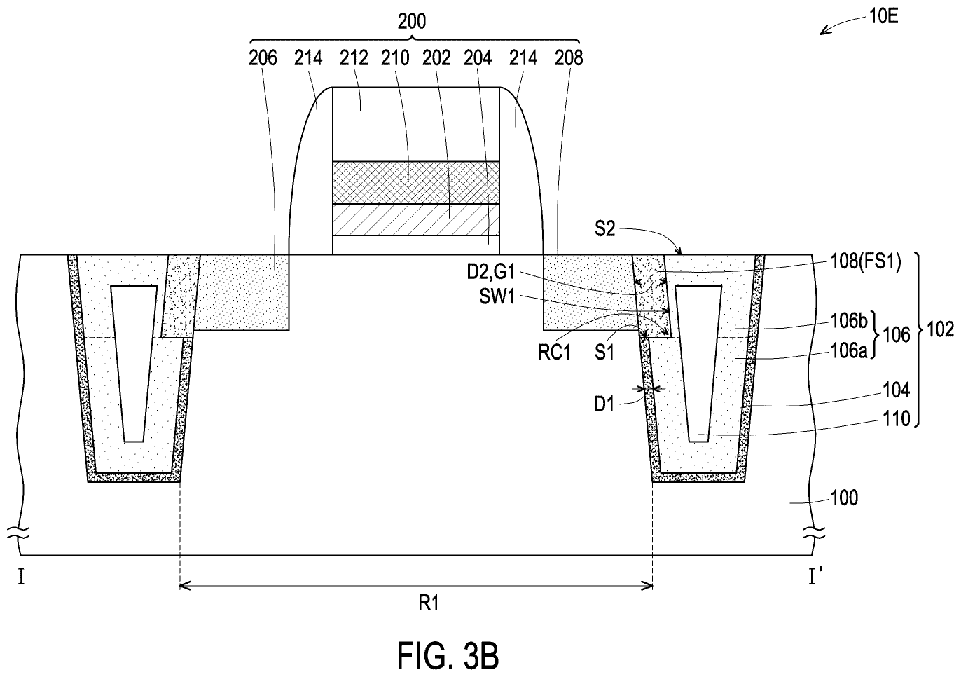

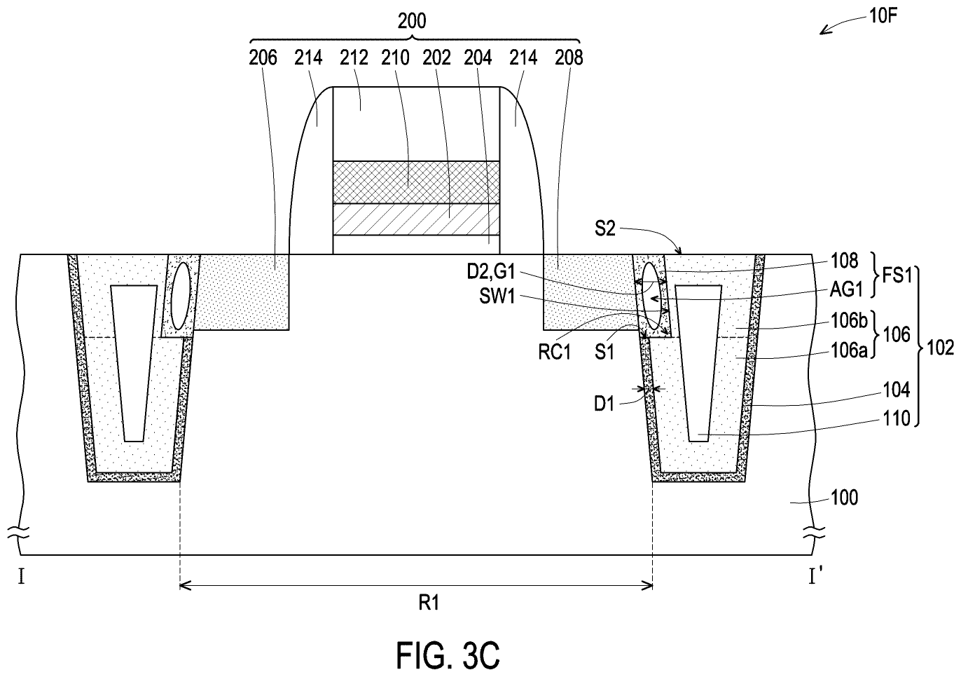

Referring to FIG. 1A to FIG. 1C and FIG. 3A to FIG. 3C, compared to the semiconductor structure 10A of FIG. 1A, the semiconductor structure 10B of FIG. 1B, and the semiconductor structure 10C of FIG. 1C, the isolation structure 102 in the semiconductor structure 10D of FIG. 3A, the semiconductor structure 10E of FIG. 3B, and the semiconductor structure 10F of FIG. 3C may further include a dielectric layer 110. The dielectric layer 110 is located in the dielectric layer 106. The dielectric layer 110 may be surrounded by the dielectric layer 106. The dielectric constant of the dielectric layer 110 may be smaller than the dielectric constant of the dielectric layer 106. In some embodiments, the second portion 106b in FIG. 3A to FIG. 3C may be a multilayer structure. In some embodiments, the material of the dielectric layer 110 may be oxide (e.g., silicon oxide such as spin on glass (SOG)). In addition, in FIG. 1A to FIG. 1C and FIG. 3A to FIG. 3C, the same or similar components are denoted by the same reference symbols, and the description thereof is omitted.

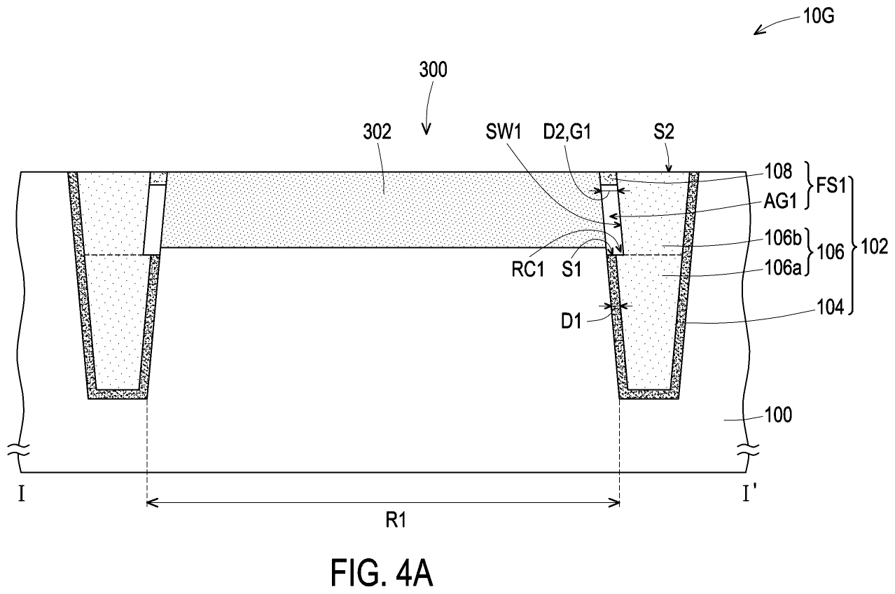

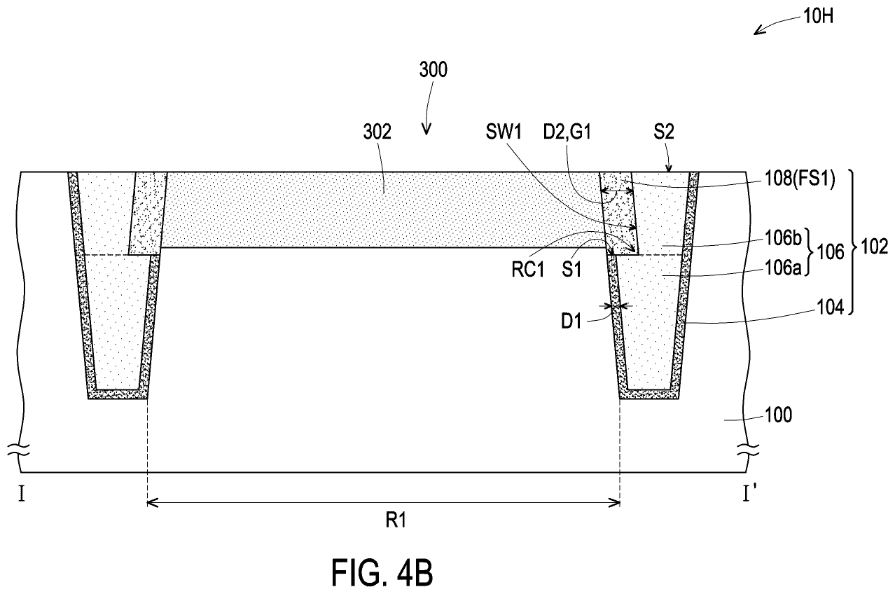

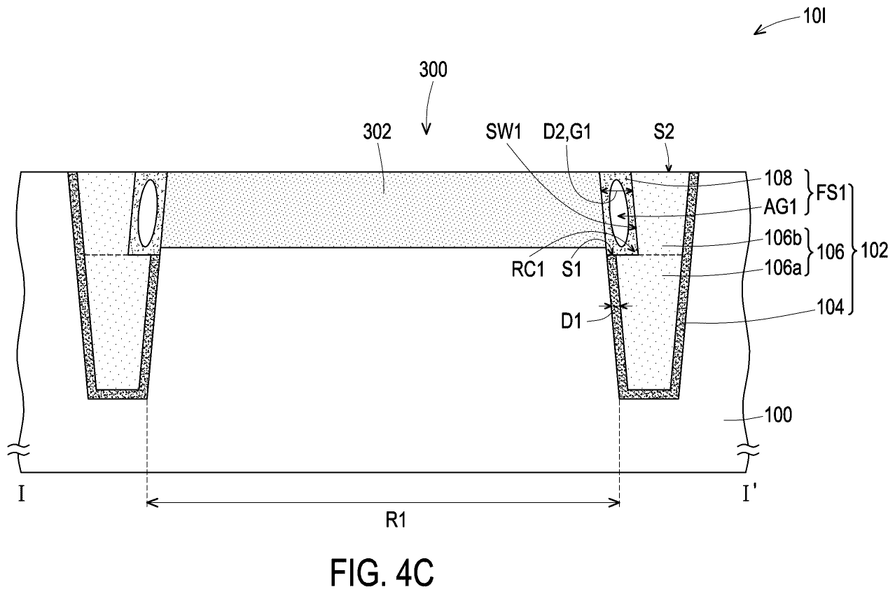

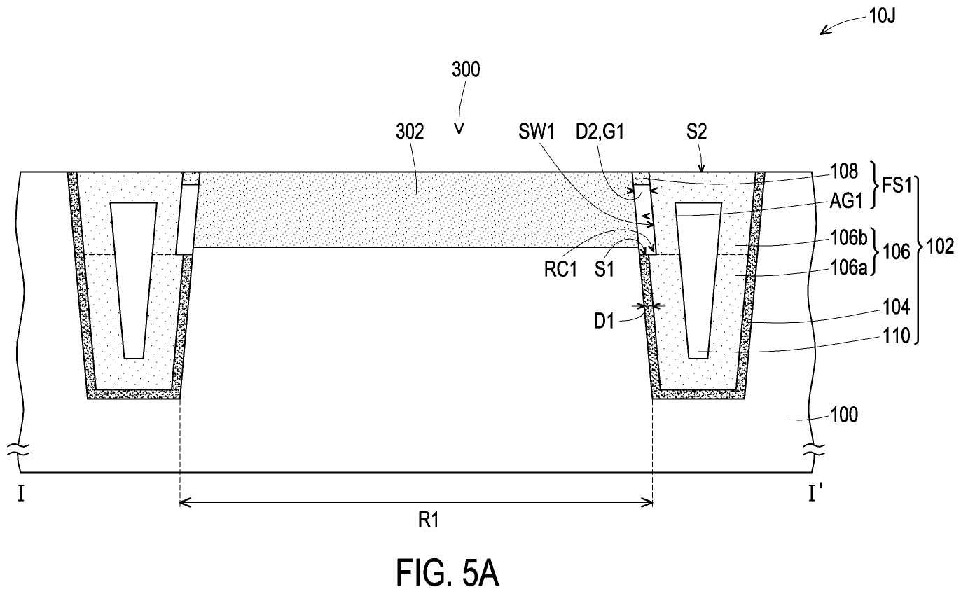

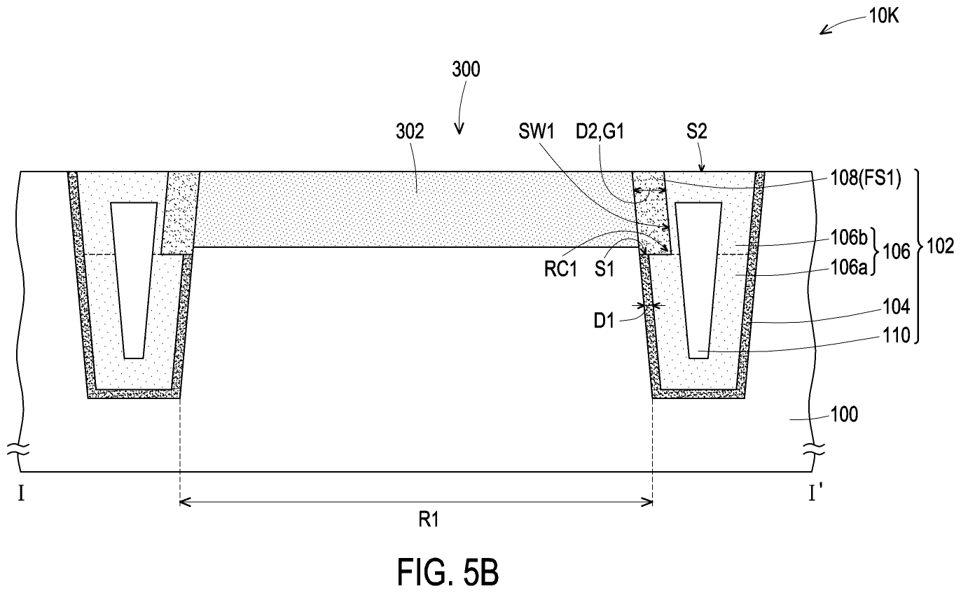

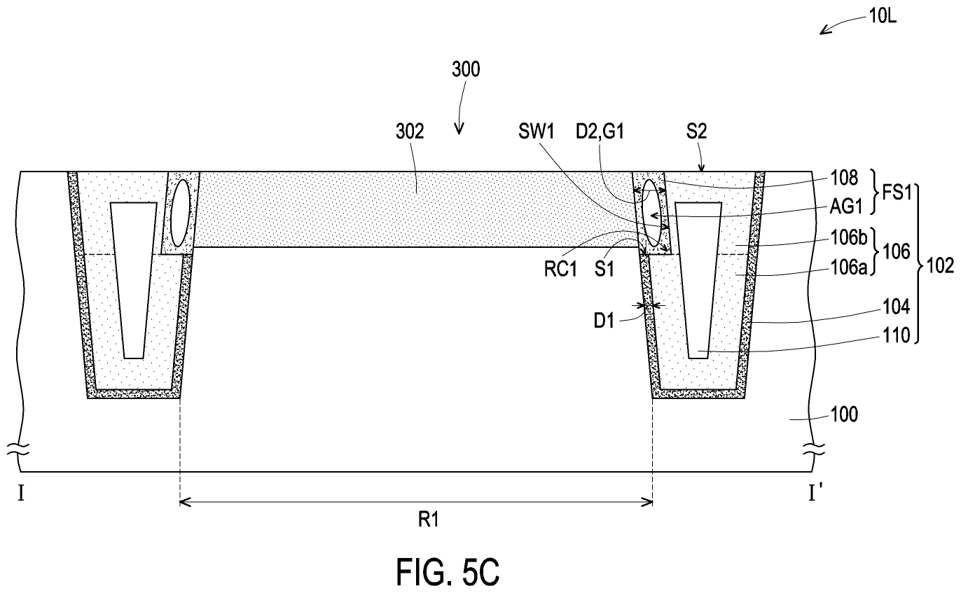

Referring to FIG. 1A to FIG. 1C and FIG. 3A to FIG. 5C, the semiconductor device 200 in the semiconductor structure 10A of FIG. 1A, the semiconductor structure 10B of FIG. 1B, the semiconductor structure 10C of FIG. 1C, the semiconductor structure 10D of FIG. 3A, the semiconductor structure 10E of FIG. 3B, and the semiconductor structure 10F of FIG. 3C is replaced with a semiconductor device 300 to form the semiconductor structure 10G of FIG. 4A, the semiconductor structure 10H of FIG. 4B, the semiconductor structure 10I of FIG. 4C, the semiconductor structure 10J of FIG. 5A, the semiconductor structure 10K of FIG. 5B, and the semiconductor structure 10L of FIG. 5C. The semiconductor device 300 may be a resistor device. The semiconductor device 300 may include a doped region 302. In addition, in FIG. 1A to FIG. 1C and FIG. 3A to FIG. 5C, the same or similar components are denoted by the same reference symbols, and the description thereof is omitted.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate comprising a device region; and
an isolation structure located in the substrate and surrounding the device region, wherein
the isolation structure comprises:
a first dielectric layer and a second dielectric layer located in the substrate, wherein the first dielectric layer is located between the second dielectric layer and the substrate, and the second dielectric layer comprises:
a first portion; and
a second portion located on the first portion, wherein a distance between the second portion and the substrate in the device region in a direction parallel to a top surface of the substrate is greater than a distance between the first portion and the substrate in the device region in the direction parallel to the top surface of the substrate.

2. The semiconductor structure according to claim 1, wherein a dielectric constant of the first dielectric layer is smaller than a dielectric constant of the second dielectric layer.

3. The semiconductor structure according to claim 1, wherein the second dielectric layer has a recess, and the recess is adjacent to the device region.

4. The semiconductor structure according to claim 3, wherein the recess is located between the second portion and the substrate in the device region.

5. The semiconductor structure according to claim 1, wherein an upper surface of the first dielectric layer adjacent to the device region is lower than a top surface of the second dielectric layer.

6. The semiconductor structure according to claim 1, wherein the first dielectric layer is not in direct contact with a sidewall of the second portion adjacent to the device region.

7. The semiconductor structure according to claim 1, wherein there is a gap between the second portion and the substrate in the device region, and the isolation structure further comprises:
a filling structure located between the second portion and the substrate in the device region, wherein the filling structure comprises:
a filling layer only located between a top portion of the second portion and the substrate in the device region and sealing a top portion of the gap; and
an air gap located between the second portion and the substrate in the device region, between the filling layer and the first dielectric layer, and between the filling layer and the first portion.

8. The semiconductor structure according to claim 7, wherein the air gap is in direct contact with the substrate, the filling layer, the first dielectric layer, the first portion, and the second portion.

9. The semiconductor structure according to claim 7, wherein a dielectric constant of the filling layer and a dielectric constant of the air gap are smaller than a dielectric constant of the second dielectric layer.

10. The semiconductor structure according to claim 1, wherein there is a gap between the second portion and the substrate in the device region, and the isolation structure further comprises:
a filling structure located between the second portion and the substrate in the device region, wherein the filling structure comprises:
a filling layer filling up the gap.

11. The semiconductor structure according to claim 10, wherein there is no air gap in the filling layer.

12. The semiconductor structure according to claim 10, wherein a dielectric constant of the filling layer is smaller than a dielectric constant of the second dielectric layer.

13. The semiconductor structure according to claim 1, wherein there is a gap between the second portion and the substrate in the device region, and the isolation structure further comprises:
a filling structure located between the second portion and the substrate in the device region, wherein the filling structure comprises:
a filling layer filling the gap and sealing the gap; and
air gap located in the filling layer and surrounded by the filling layer.

14. The semiconductor structure according to claim 13, wherein the air gap is not in direct contact with the substrate, the first dielectric layer, and the second dielectric layer.

15. The semiconductor structure according to claim 13, wherein a dielectric constant of the filling layer and a dielectric constant of the air gap are smaller than a dielectric constant of the second dielectric layer.

16. The semiconductor structure according to claim 1, wherein the isolation structure further comprises:
a third dielectric layer located in the second dielectric layer and surrounded by the second dielectric layer, wherein a dielectric constant of the third dielectric layer is smaller than a dielectric constant of the second dielectric layer.

17. The semiconductor structure according to claim 1, further comprising:
a semiconductor device located in the device region.

18. The semiconductor structure according to claim 17, wherein the semiconductor device comprises an active device or a passive device.

19. The semiconductor structure according to claim 17, wherein the semiconductor device comprises a transistor device or a resistor device.

20. A semiconductor structure, comprising:
a substrate comprising a device region;
an isolation structure located in the substrate and surrounding the device region, wherein
the isolation structure comprises:
a first dielectric layer and a second dielectric layer located in the substrate, wherein the first dielectric layer is located between the second dielectric layer and the substrate, and the second dielectric layer comprises:
a first portion; and
a second portion located on the first portion, wherein a distance between the second portion and the substrate in the device region in a direction parallel to a top surface of the substrate is greater than a distance between the first portion and the substrate in the device region in the direction parallel to the top surface of the substrate; and
a semiconductor device located in the device region and comprising:
a gate located on the substrate;
a dielectric layer located between the gate and the substrate; and
a first doped region and a second doped region located in the substrate on two sides of the gate.
